(19) United States
(12) Patent Application Publication
(10) Pub. No.: US 2025/0185288 A1
(43) Pub. Date: Jun. 5, 2025

(54) SEMICONDUCTOR DEVICE AND METHOD OF MANUFACTURING THE SAME

(71) Applicant: Infineon Technologies Austria AG, Villach (AT)

(72) Inventors: Heimo Hofer, Steindorf (AT); Quang Tien Tran, Villach (AT)

(21) Appl. No.: 18/958,439

(22) Filed: Nov. 25, 2024

(30) Foreign Application Priority Data
Dec. 5, 2023 (DE) 102023212223.5

(51) Int. Cl. H10D 30/66; H10D 30/01; H10D 64/27

(52) U.S. Cl. CPC H10D 30/668; H10D 30/0297; H10D 64/513

(57) ABSTRACT

The present application relates to a semiconductor device with a gate region and/or field electrode region in a vertical trench. A dielectric of the gate region and/or field electrode region includes silicon oxide doped with a semi-metal or alkali metal such as being doped with boron.

### TECHNICAL FIELD

The present disclosure relates to a semiconductor device and a method of manufacturing the semiconductor device.

### BACKGROUND

The semiconductor device may comprise a semiconductor body in which a device structure may be formed. Depending for instance on the device type and set-up, it can comprise load terminals on the same side or on opposite sides of the semiconductor body, for instance a source and a drain region in case of a transistor structure. A gate region and/or a field electrode region may in particular be arranged in a vertical trench which extends into the semiconductor body.

### SUMMARY

It is an object of the present application to provide an advantageous semiconductor device.

According to some embodiments, a dielectric of the gate region and/or a dielectric of the field electrode region comprises silicon oxide doped with a semi-metal or alkali metal, in particular with boron.

This doping or alloying may for instance “smoothen” the oxide, for example reduce sharp curvatures or edges in the geometry of the dielectric. This can for instance have a positive impact on the electrical properties of the device. Since the gate and/or field electrode region is arranged in a trench, the dielectric (silicon oxide) is in a sense embedded into or enclosed by the semiconductor body, wherein these geometric boundary conditions together with the combination of different materials may result in a mechanical stress. Depending on the stress level, for instance crystal-defects and leakage-currents can result (depending for instance also on CTE mismatch and volume).

Particular embodiments and features are provided in this description and in the dependent claims. Therein, the individual features shall be disclosed independently of a specific claim category, the disclosure relates to apparatus and device aspects, but also to method and use aspects. If for instance a device manufactured in a specific way is described, this is also a disclosure of a respective manufacturing method, and vice versa. In general words, an approach of this application is to provide a dielectric in a gate and/or field electrode trench with a doping, in particular with a semi-metal or alkali metal doping.

A respective doping, for instance with Li₂O, Na₂O, K₂O or in particular B₂O₃ may for instance increase a “flowability” of the silicon oxide, for example generate a small amount of liquid phase during a later anneal process. The liquid phase can increase the flowing characteristics and cause an “automatic” reshaping and smoothening, for instance due to an altered surface-tension or viscosity. The present approach may in particular relate to the combination of a silicon oxide based dielectric with a semiconductor body made of silicon or silicon carbide, for instance an Si or SiC substrate with one or several Si or SiC epitaxial layers.

In general, the device may for instance have only the field electrode region in a trench, whereas the gate electrode can be arranged above the semiconductor body, for instance as a planar gate. Alternatively, the device does not necessarily comprise a field electrode region, having for instance only the gate region in a trench. In particular, however, the device may comprise a gate region and a field electrode region, both in a vertical trench. As detailed below, the gate and field electrode region may be arranged in the same trench, stacked one above the other, or aside each other in separate trenches.

Generally, the device may for instance be an insulated-gate bipolar transistor, IGBT. In particular, the device may be a transistor, having for example a source region, a drain region and a body region in the semiconductor body. In addition, it may comprise a drift region between the body region and the drain region, e.g. made of the same doping type but with a lower doping concentration compared to the drain region. The source and drain region, as well as drift region, if present, can be made of a first doping type, whereas the body region may be made of a second doping type. In the exemplary embodiments, the first type is n-type and the second type is p-type.

The gate region in the trench may capacitively couple to the body region via the dielectric (“gate dielectric”) and/or the field electrode may capacitively couple to the drift region via the dielectric (“field dielectric”). In other words, the vertical trench with the field electrode may extend into the drift region and/or the vertical trench with the gate electrode may extend into the body region. The vertical trench may solely comprise the gate region, e.g. be a “gate trench”, or may solely comprise the field electrode region, e.g. be a “field electrode trench”, or may comprise a gate region and a field electrode region, e.g. be a “combined gate and field electrode trench”.

Aside, the vertical trench with the gate electrode, a channel region may be formed in the body region, wherein a direction of the current flow in the channel region may be vertical or lateral. The load terminals, for instance source and drain region, may be arranged on the same side of the semiconductor body, for example in case of a lateral current flow or in case of a vertical current flow in combination with a sinker implant routing the current upwards again. In particular embodiments, the load contacts of the device are arranged on opposite sides of the semiconductor body, for instance a source terminal at a first side and a drain terminal at a vertically opposite second side.

The vertical trench extends vertically into the semiconductor body, for instance from a first side of the semiconductor body. In general, the vertical trench may be overgrown, namely covered by an epitaxial layer or layers, in other words embedded vertically into the semiconductor body. In particular, it may reach up to a first side of the semiconductor body, which may also be referred to as “frontside”. Seen in a vertical top view, the trench may have an elongated shape, e.g. an elongated extension in a lateral direction. Alternatively or in addition, a vertical trench, in particular field electrode trench, may have a needle or columnar shape, which may for instance be combined with an elongated gate trench surrounding the needle-shaped field electrode and forming the cell pattern, see in detail below.

The dielectric may be arranged at a sidewall of the trench, for instance capacitively coupling the gate electrode to the body region aside or the field electrode to the drift region aside. Additionally, the dielectric may also extend at the bottom of the trench, for example below the gate electrode in case of a gate trench or below the field electrode in case of a field electrode trench or combined gate and field electrode trench. The dielectric may in particular extend as an integral layer at the side wall and the bottom of the vertical trench.

In an embodiment, the dielectric has a larger thickness at the bottom than at the sidewall of the vertical trench. The respective thickness may be taken perpendicularly to the respective surface of the trench sidewall or bottom, for instance vertically at the bottom of the trench and basically horizontally at the sidewall of the trench. The different thicknesses may for instance be obtained in an anneal step, wherein the increased flowing characteristics of the doped silicon oxide may cause a reshaping and material redistribution downwards. In case of a varying thickness, maximum values may be compared, the maximum thickness at the bottom taken for instance along a vertical center axis of the trench.

In an embodiment, a dopant concentration, in particular boron concentration, in the dielectric is larger at the bottom than at the sidewall of the vertical trench. At the bottom, a stress state or stress distribution may be particularly relevant due to the geometrically restricted space there. Vice versa, the higher dopant concentration and increased flowability may for instance improve the reshaping or smoothening. In case of a concentration varying over the thickness, in particular at the bottom (see below), a respective mean value of the doping concentration averaged over the thickness may be considered.

In an embodiment, the dopant concentration, in particular boron concentration in the dielectric at the bottom of the vertical trench has a gradient. It may in particular decrease downward, the dopant concentration at an upper side of the dielectric at the bottom being for instance smaller than the dopant concentration at the lower side of the dielectric at the bottom. The dopant concentration at the upper side of the dielectric at the bottom may for instance be basically the same as the dopant concentration at the sidewall (see above).

In an embodiment, a dopant concentration, in particular boron concentration in the dielectric is 0.1% at minimum, further lower limits being for instance 1%, 5% or 10%. The percentages are mole percent, also referred to as “molar fraction” and abbreviated “mol %”. It may be obtained as a ratio between the amount of dopant/boron oxide (expressed in moles) and the amount of all constituents in the dielectric (e.g. silicon oxide+dopant/boron oxide, also expressed in moles). Possible upper limits may be 50%, 40%, 30% or 20%. In case of a varying dopant concentration, for instance at the bottom compared to the sidewall and/or at the bottom in a gradient, these values may in particular relate to a maximum dopant concentration, taken for instance at the lower side of the dielectric at the bottom of the vertical trench.

In an embodiment, the field electrode and the vertical trench comprising the field electrode respectively have a needle shape. The needle-shaped trench may for instance have a comparably small width compared to its depth, for example at least a three-, five-, ten-, or twenty-fold depth compared to the width taken at its upper end (possible upper limits being for instance a 150-, 100- or 50-fold depth). In absolute values, the needle trench may for instance have a depth of for instance not more than 20 μm, 15 μm, 10 μm or 8 μm, possible lower limits being for example 2 μm, 4 μm or 6 μm.

Independently of these details, the needle shaped trench may for instance have an inverse dome-like shape at the bottom, which may result in a geometrically restricted mechanical stress state (like in half sphere-shaped dome). Vice versa, the relaxation or smoothening of the doped silicon oxide can be of a particular interest in case of the needle trench. The stress state or shape of the dielectric at the bottom may for instance influence the breakdown voltage, for example drain-source breakdown voltage, or a zero gate voltage current, the smoothening of the oxide improving also an electrical device behavior.

In an embodiment, the gate region of the device is arranged in the same vertical trench above the field electrode region. Seen in a vertical top view, the respective trench may have an elongated extension, the device comprising for instance a plurality of device cells, each having a respective elongated trench, for example arranged in a parallel stripe pattern. An “elongated” extension may for instance mean a greater lateral length compared to the vertical depth and/or lateral width of the trench. Independently of these details, a respective trench comprising the gate and the field electrode below may for instance extend down into a drift region in the semiconductor body, wherein an upper portion of the trench with the gate region may extend through the body region.

A method of manufacturing a semiconductor device with a gate and/or field electrode region in a vertical trench may comprise: etching the vertical trench; forming a dielectric; applying a semi-metal or alkali metal doping to the dielectric, in particular a boron doping.

The dielectric may in particular be formed to cover a sidewall and a bottom of the vertical trench, in general for instance as a thermal oxide.

In a particular embodiment, the formation of the dielectric comprises a deposition of tetraethoxysilane (TEOS) and a subsequent anneal step to form silicon oxide from the TEOS. The anneal temperature may for instance be at least 900° C. and not more than 1200° C. For the sake of wording, the step is referred to as “first anneal step”, though it may in general be the sole anneal step in the formation of the dielectric.

In an embodiment, the first anneal step is performed in an atmosphere comprising at least one of oxygen and water. The presence of O₂ or H₂O, e.g. wet atmosphere, may for instance “smoothen” the shape of the dielectric, for example to a lower surface tension in the presence of O₂ or H₂O. In other words, the improvement of the flowing characteristics as discussed above for the doped dielectric may alternatively or in addition also be achieved in a respective atmosphere in the anneal step.

This shall also be disclosed independently of the semi-metal/alkali/boron doping. In particular, a method of manufacturing a semiconductor device with a gate and/or field electrode region in a vertical trench may comprise: etching the vertical trench; depositing TEOS; applying a (first) anneal step to form silicon oxide from the TEOS in an atmosphere comprising O₂ and/or H₂O.

In an embodiment, independently of whether combined with the doping or not, the atmosphere comprising O₂ and/or H₂O is applied at a temperature of at least 1125° C., in particular at least 1150° C. In other words, the temperature may in particular be between 1150° C. and 1200°° C.

In an embodiment relating to the doped dielectric, the doping may be applied in between the TEOS deposition and the (first) anneal step. In other words, a dopant diffusion or oxidation, in particular boron oxide formation, may be made in the same step as the silicon oxide formation.

In an alternative embodiment, the boron doping is applied after the first anneal step, e.g. is applied to the silicon oxide derived from the TEOS beforehand. After doping the silicon oxide, a subsequent second anneal step may be applied, for instance to form a boron oxide.

A method of designing a semiconductor device may comprise adapting a coefficient of thermal expansion (CTE) of the dielectric, for example by choosing a respective alloy for the dielectric. For instance, a doping with aluminum oxide or titanium oxide may increase the CTE, whereas a boron oxide doping may lower the CTE. The CTE of the dielectric can for instance have an impact on the mechanical stress in the dielectric. In comparison to the semiconductor material, for example silicon, the silicon oxide can have a different, in particular smaller CTE.

Considering an oxide formation at an increased temperature (e.g. anneal step, see above), the dielectric and the semiconductor body may be in a basically stress-free state at high temperatures, wherein the semiconductor body having a higher CTE and, in consequence, contracting more upon cooling may cause a compressive stress in the dielectric at lower temperatures, in particular at the interface between the semiconductor body and the dielectric. Vice versa, a tensile stress may be introduced into the semiconductor material. The tensile stress may for instance improve or increase the electron mobility, so that lowering the CTE of the dielectric, for instance with a boron oxide doping, may increase the electron mobility, e.g. lower an on-resistance.

### BRIEF DESCRIPTION OF THE DRAWINGS

Below, the semiconductor device and related methods are explained in further detail by means of exemplary embodiments. Therein, the individual features can also be relevant for the disclosure in a different combination.

FIG. 1 shows a cross-sectional view of a semiconductor device with separate gate and field electrode trenches;

FIG. 2 shows a detailed view of a vertical trench with a dielectric;

FIG. 3 illustrates a reshaping of a dielectric in a vertical trench;

FIG. 4 illustrates another semiconductor device with a combined gate and field electrode trench in a cross-sectional view;

FIGS. 5a, b summarize some manufacturing steps in flow diagrams; and

FIG. 6 illustrates an impact of an anneal atmosphere on the reshaping of a dielectric.

### DETAILED DESCRIPTION

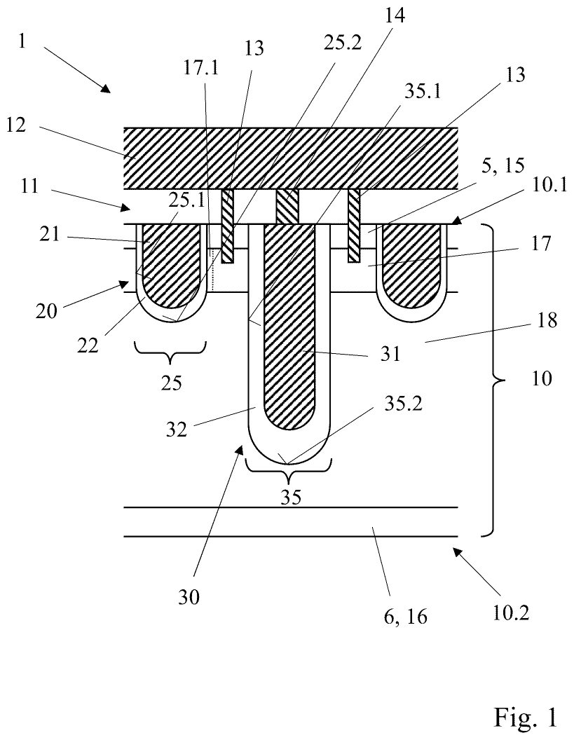

FIG. 1 shows a semiconductor device 1 in a vertical cross-section. In a semiconductor body 10, a first load terminal 5 and a second load terminal 6 are formed, in the example shown the first load terminal 5 at a first side 10.1 of the semiconductor body 10 and the second load terminal 6 at a second side 10.2. In case of the FET, the first load terminal 5 is a source region 15 and the second load terminal 6 is a drain region 16. In between, a body region 17 and drift region 18 are arranged, the source region 15, drift region 18 and drain region 16 being for instance n-type and the body region 17 being p-type.

From the first side 10.1 of the semiconductor body 10, a vertical trench 25 extends into the semiconductor body 10, which is a gate trench in the example shown. It comprises a gate region 20 with a gate electrode 21 and a dielectric 22. The dielectric 22 is arranged at a sidewall 25.1 and a bottom 25.2 of the vertical trench 25, it may in particular capacitively couple the gate electrode 21 to the body region 17, e.g. to a channel region 17.1 aside the vertical trench 25.

A field electrode region 30 is arranged in a separate vertical trench 35 which extends from the first side 10.1 of the semiconductor body 10 further downward into the drift region 18. The field electrode region 30 comprises a field electrode 31 and a dielectric 32, wherein the dielectric 32 covers a sidewall 35.1 and a bottom 35.2 of the vertical trench 35. Via the dielectric 32, the field electrode 31 capacitively couples to the drift region 18, for instance for a field shaping. In the example shown, the field electrode 31 is connected to the source region 15, namely is on source potential. The vertical trench 35 and the filed electrode 31 are needle-shaped, wherein the vertical trench 25 with the gate electrode 21 surrounds the needle trench, forming for instance a polygonal cell pattern seen in a top view.

On the first side 10.1 of the semiconductor body 10, an insulation layer 11 and a metallization layer 12 are arranged. Via the vertical interconnects 13, 15 the metallization layer 12 connects to the source region 15 and to the field electrode 31. The gate electrode 21 may be connected outside the drawing plane. The metallization stack may comprise one single metal layer, as shown, or a plurality of metal layers for a further wiring.

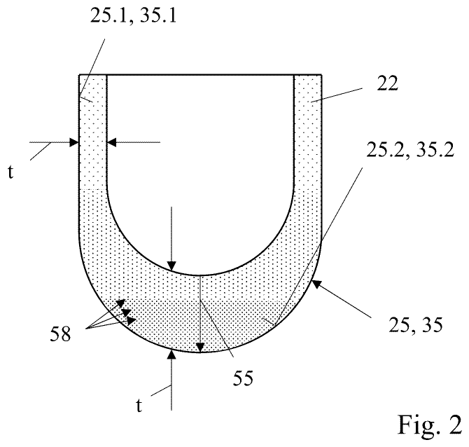

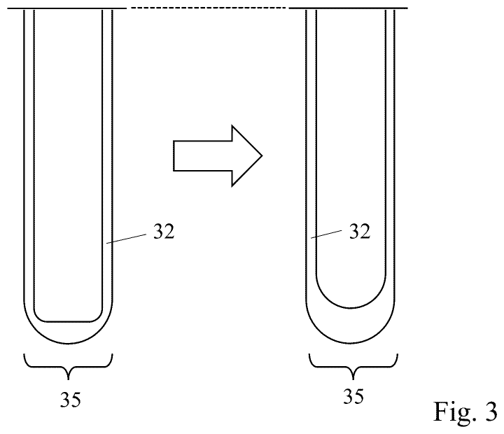

FIG. 2 shows a detailed view of a vertical trench 25, 35 that can be a gate or field electrode trench as shown in FIG. 1. The dielectric 22, 32 is doped with a semi-metal or alkali metal, in the example shown with boron. The doping may for instance allow for a certain reshaping of the dielectric 22, 32 (see FIG. 3 for illustration), e.g. provide for a certain smoothening. The thickness t of the dielectric 22, 32 may be smaller at the sidewall 25.1, 35.1 than at the bottom 25.2, 35.2 of the vertical trench 25, 35, which may result from the reshaping.

In the dielectric 22, 32 a doping agent 58, e.g. boron or boron oxide, is shown schematically. It may be distributed in homogeneously in the dielectric 22, 32 for instance having a lower concentration at the sidewall 25.1, 35.1 than at the bottom 25.2, 35.2 and/or having a gradient 55 at the bottom 25.2, 35.2, e.g. with a density increasing downwards.

FIG. 3 illustrates a reshaping of a dielectric 32, e.g. field dielectric in a deep trench. On the left, the dielectric 32 is shown after deposition, it may basically have the same thickness t at the sidewall 35.1 and at the bottom 35.2. In an anneal step (see below), the presence of the doping agent may increase the flowing characteristics of the dielectric 32, allowing for a certain redistribution or reshaping of the dielectric 32, as illustrated in FIG. 3 on the right. As discussed above, this may even improve electrical device characteristics.

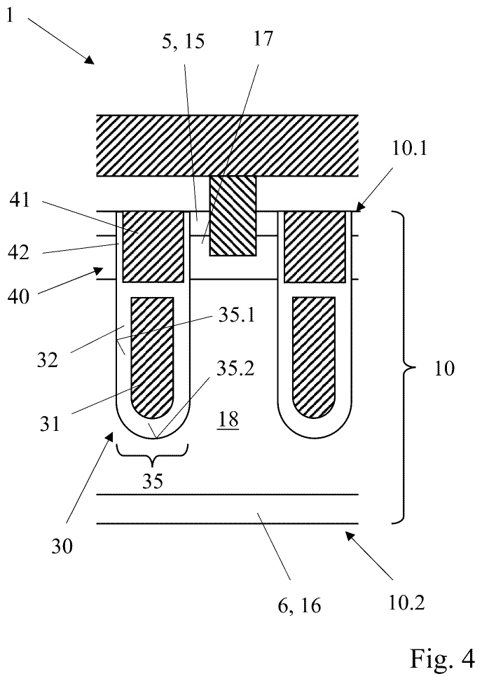

FIG. 4 shows another semiconductor device 1. Generally, in this disclosure, the like reference numerals indicate the like parts or parts having the like function, reference being made to the description of the other figures as well. Below, mainly the differences compared to the device of FIG. 1 are highlighted.

The gate region 40 is arranged above the field electrode region 30 in the same vertical trench 35, the field electrode 31 and gate electrode 41 are stacked above each other. The dielectric 32 of the field electrode region 30 may have a doping as discussed above, alternatively or in addition the dielectric 42 of the gate electrode region 40 may have a doping as discussed above, for instance with reference to FIG. 2. The dielectric 22 may be fabricated in a subsequent process step compared to the dielectric 32 of the field electrode region 30, which may allow for adjusting the parameters, e.g. thickness and/or doping, as respectively required.

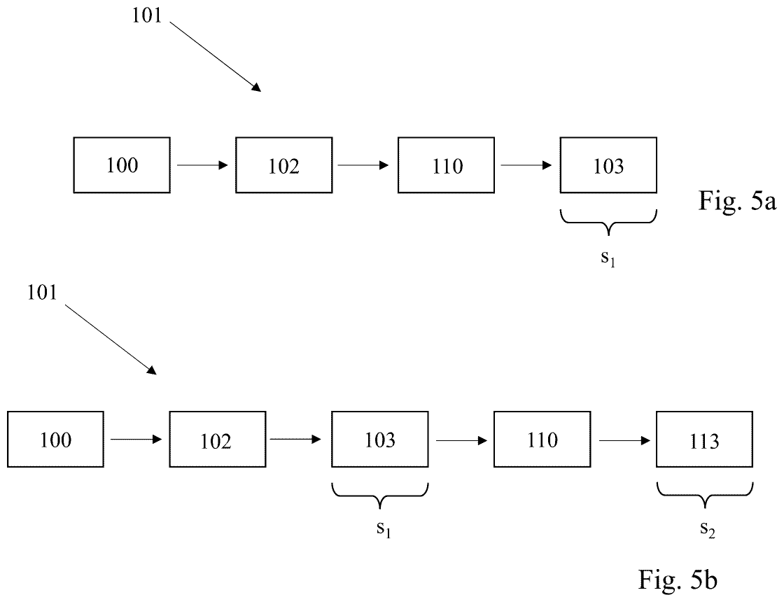

FIG. 5a summarizes some method steps for manufacturing a semiconductor device with a gate or field electrode trench. After etching 100 the vertical trench, the dielectric is formed 101, for instance by depositing 102 TEOS. By applying 103 a first anneal step s₁, silicon oxide is formed from the TEOS. Before the first anneal step s₁, a boron doping may be applied 110 to the dielectric, which can increase the flowing characteristics of the dielectric in the subsequent anneal step s₁.

FIG. 5b summarizes an alternative way of manufacturing the device, wherein the boron doping is applied 110 after the first anneal step s₁. Thus, the doping agent is introduced to the silicon oxide formed before from the TEOS, wherein a second anneal step s₂ is applied 113 after the doping.

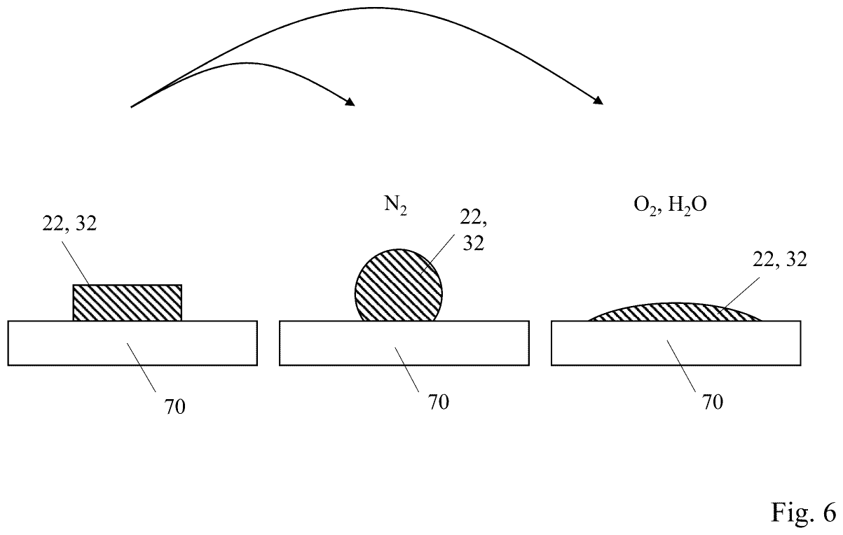

Alternatively or in addition to the doping of the dielectric, its flowing characteristics may also be influenced via the atmosphere during annealing. FIG. 6 illustrates a different behavior or reshaping of a dielectric 22, 32 on a substrate 70. The atmosphere applied may influence a surface tension, wherein the presence of nitrogen (in the middle) can increase a surface tension of the dielectric 22, 32, e.g. cause a certain dewetting. Vice versa, the presence of oxygen and/or water may lower a surface tension and improve the flowing characteristics, see the image on the right.

What is claimed is:

1. A semiconductor device, comprising:
a semiconductor body;
a gate region in a vertical trench extending into the semiconductor body;
wherein the gate region comprises:
a gate electrode; and
a dielectric,
wherein the dielectric comprises silicon oxide doped with a semi-metal or alkali metal.

2. The semiconductor device of claim 1, wherein the dielectric is arranged at a side wall and a bottom of the vertical trench, and wherein the dielectric has a larger thickness at the bottom than at the side wall.

3. The semiconductor device of claim 1, wherein the dielectric is arranged at a side wall and a bottom of the vertical trench, and wherein a boron concentration in the dielectric is larger at the bottom than at the side wall.

4. The semiconductor device of claim 1, wherein the dielectric is arranged at least at a bottom of the vertical trench, and wherein a boron concentration in the dielectric at the bottom has a gradient and decreases downward.

5. The semiconductor device of claim 1, wherein a boron concentration in the dielectric is 0.1% at minimum and 50% at maximum.

6. The semiconductor device of claim 1, wherein the field electrode and the vertical trench both have a needle shape.

7. The semiconductor device of claim 1, further comprising:
a gate region arranged above the field electrode region in the vertical trench.

8. A semiconductor device, comprising:
a semiconductor body;
a field electrode region in a vertical trench extending into the semiconductor body;
wherein the field electrode region comprises:
a field electrode; and
a dielectric,
wherein the dielectric comprises silicon oxide doped with boron.

9. The semiconductor device of claim 8, wherein the dielectric is arranged at a side wall and a bottom of the vertical trench, and wherein the dielectric has a larger thickness at the bottom than at the side wall.

10. The semiconductor device of claim 8, wherein the dielectric is arranged at a side wall and a bottom of the vertical trench, and wherein a boron concentration in the dielectric is larger at the bottom than at the side wall.

11. The semiconductor device of claim 8, wherein the dielectric is arranged at least at a bottom of the vertical trench, and wherein a boron concentration in the dielectric at the bottom has a gradient and decreases downward.

12. The semiconductor device of claim 8, wherein a boron concentration in the dielectric is 0.1% at minimum and 50% at maximum.

13. The semiconductor device of claim 8, wherein the field electrode and the vertical trench both have a needle shape.

14. The semiconductor device of claim 8, further comprising:
a gate region arranged above the field electrode region in the vertical trench.

15. A method of manufacturing a semiconductor device with a gate or field electrode region in a vertical trench, the method comprising:
etching the vertical trench into a semiconductor body;
forming a dielectric in the vertical trench; and
applying a boron doping to the dielectric.

16. The method of claim 15, wherein forming the dielectric comprises:
depositing tetraethoxysilane; and
applying a first anneal step to form silicon oxide from the TEOS.

17. The method of claim 16, wherein the first anneal step is performed in an atmosphere comprising oxygen and/or water.

18. The method of claim 17, wherein the atmosphere is applied at a temperature of at least 1125° C.

19. The method of claim 16, wherein the boron doping is applied in between the depositing tetraethoxysilane and the applying the first anneal step.

20. The method of claim 16, wherein the boron doping is applied after the applying the first anneal step, the method further comprising:
forming a boron oxide by applying a subsequent second anneal step.
